(19) United States
(12) Patent Application Publication
(10) Pub. No.: US 2007/0173657 A1
(43) Pub. Date: Jul. 26, 2007

(54) Tetraphenylsilane-carbazole compound, its preparation method and its use as host material for dopants of organic light emitting diode

(75) Inventors: Chin-Ti Chen, Taipei (TW); Min-Fei Wu, Taipei (TW); Shi-Jay Yeh, Taipei (TW)

Correspondence Address: BACON & THOMAS, PLLC, 625 SLATERS LANE, FOURTH FLOOR, ALEXANDRIA, VA, 22314, US

(73) Assignee: Academia Sinica, Taipei (TW)

(21) Appl. No.: 11/339,487

(22) Filed: Jan. 26, 2006

(51) Int. Cl. H01L 51/54; C07F 7/10

(52) U.S. Cl. 556/413; 548/440; 556/432; 428/690; 428/917; 428/448; 313/504; 313/506; 257/40; 257/E51.046; 257/E51.05

(57) ABSTRACT

The tetraphenylsilane-carbazole compound of this invention has the following general formula: 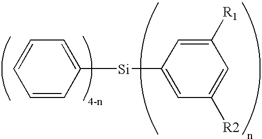
wherein R1 and R2 are H, halogen or carbazole having the formula of 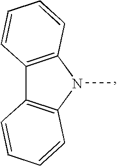
with at least one of R1 and R2 being carbazole; n=1, 2, 3 or 4; and wherein Si and N substituents are in meta positions on the benzene ring; or 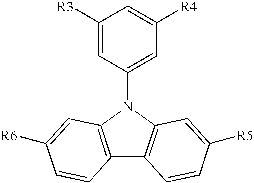
wherein R3, R4, R5 and R6 are H, halogen or tetraphenylsilane having the formula of 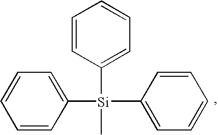 with at least one of R3, R4, R5 and R6 being tetraphenylsilane; and wherein Si and N substituents are in meta positions on the benzene ring. The invented tetraphenylsilane-carbazole compounds are prepared by mixing selected tetraphenylsilane with carbazole in the existence of additives and reacting them under heated conditions, or by mixing selected carbazole with butyl metallic and reacting them under relatively lower temperature. The products may be used as host material for dopants for organic light emitting diode (OLED).

### FIELD OF INVENTION

The present invention relates to tetraphenylsilane-carbazole compounds, their preparation method and their use as host material for dopants for organic light emitting diode (OLED), especially to a series of host materials for dopants for OLED with higher glass transition temperature, higher triplet-state excitation energy and long-term stability.

### BACKGROUND OF THE INVENTION

Since organic light emitting diode (OLED) was discovered in late 1980's, researchers in both academia and industry throughout the world have been working very hard to improve its performance. Successful improvements were obtained by the use of new emissive materials, modifications of device structure etc. in order to have higher luminance and power efficiencies, brighter RGB colors, and linger term operational stability. It was not until the discovery of organic phosphorophores did researchers begin seriously to look into white OLEDs (WOLEDs), in order to realize thin-film solid-state lightings. In the application of lightings, power efficiency is one of the most important concerns. For example, in the conventional white incandescent, the power efficiency of 10-15 lm/W is typical. For a tube fluorescent lamp, the power efficiency of 70 lm/W is typically required. Highly efficient organic phosphorescent OLEDs based on cyclometalated iridium complexes are well known. As reported, such materials performed as high as 19% (or 70 lm/W) electro-luminescence (EL) efficiencies working as green LED and 10% (or 8 lm/W) as red LED.

There are a couple of limitations in using phosphorescence-based materials for OLED. First, Compared with the relatively long phosphorescence lifetime of the iridium complexes, if compared with the short emission lifetime of fluorescent materials, may lead to dominant triplet-triplet (T₁-T₁) annihilation at high currents. Longer emission lifetime also causes longer range of exciton diffusion (>100 nm) that could be quenched by materials in the adjacent layers of the OLED. Consequently, organic phosphorescent materials are often used as dopants and are dispersed in a suitable host material of high bandgap energy and carrier transport property. Arylamino-containing organic substances are usually chosen as such host materials and are proved working reasonably well for phosphorescent green or red materials. However, it has been found that greater difference of the triplet energies of host and the guest materials is required in order to confine the electro-generated triplet exciton in the dopant molecules.

In the case of triplet-state blue emitter, arylamino containing materials, such as 4,4′-bis(9-carbazolyl)-2,2′-biphenyl (CBP), do not have sufficient high triplet-state energy to bring about effective T₁-T₁ energy-transfer. A structurally modified host molecule, mCP (1,3-bis(9-carbazolyl)benzene) has been shown to be suitable material for phosphorescent blue dopants. CBP is a crystallinic material. It does not have a glassy structure and thus has no glass transition temperatures (T_{g}s). On the other hand, mCP has sufficient high T₁ energy but can only form unstable glassy amorphous thin films under the low T_{g} of 55° C. in solid state. The crystallinic form or low T_{g}s of CBP is detrimental to the morphological stability of the thin film materials which compose the layer-structure of the OLED.

### OBJECTIVES OF THE INVENTION

The objective of this invention is to provide a new host material for dopants of OLEDS.

Another objective of this invention is to provide a host material for dopants of OLEDs that provides higher glass transition temperature.

Another objective of this invention is to provide a host material for dopants of OLEDs that provides higher triplet-state excitation energy.

Another objective of this invention is to provide a host material for dopants of OLEDs that provides longer term stability.

Another objective of this invention is to provide a method for preparation of the above host material for dopants of OLEDS.

Another objective of this invention is to provide a series of new tetraphenylsilane-carbazole compounds.

Another objective of this invention is to provide a series of new tetraphenylsilane-carbazole compounds that may be used as major ingredient for host material for dopants of OLEDS.

Another objective of this invention is to provide a method for preparation of the above tetraphenylsilane-carbazole compounds.

Another objective of this invention is to provide a new host material for dopants of OLEDs that contains a tetraphenylsilane-carbazoble compound.

Another objective of this invention is to provide a new structure of light emit layer for OLEDs that comprises the invented host material and dopants.

### SUMMARY OF THE INVENTION

According to this invention, a tetraphenylsilane-carbazole compound is disclosed. The tetraphenylsilane-carbazole compound of this invention has the following general formula:

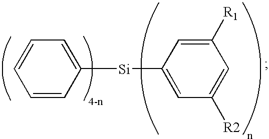

wherein R1 and R2 are H, halogen or carbazole having the formula of 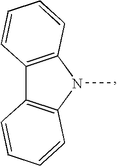
with at least one of R1 and R2 being carbazole; n=1, 2, 3 or 4; and wherein Si and N substituents are in meta positions on the benzene ring; or

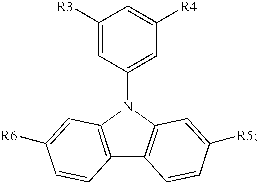

wherein R3, R4, R5 and R6 are H, halogen or tetraphenylsilane having the formula of 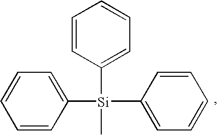
with at least one of R3, R4, R5 and R6 being tetraphenylsilane; and wherein Si and N substituents are in meta positions on the benzene ring.

In this invention, method for preparation of the invented tetraphenylsilane-carbazole compound is also disclosed. According to one aspect of the invented method, tetraphenylsilane-carbazole compounds are prepared by mixing selected tetraphenylsilane with carbazole in the existence of additives and react under heated conditions. In another aspect of the invented method, tetraphenylsilane-carbazole compounds are obtained by mixing selected carbazole with butyl metallic and reacting them under relatively lower temperature. In the first aspect of the invented method, the tetraphenylsilane may have substituents in its benzene ring. The substituents may be one or more halogens. The reaction may be conducted under the presence of solvents, catalysts and additives. The reaction temperature is preferably above 85° C., more preferably above 135° C. In the second aspect of the invented method, the butyl metallic is preferably butyl alkali and more preferably butyllithum. The reaction may be conducted under the presence of solvents, catalysts and additives. The reaction temperature is preferably below 20° C., more preferably below 0° C. The reaction may also be conducted in a Grignard fashion, i.e. reacting aromatic halide first with Mg in the presence of catalytic amount of iodine or 1,2-dibromoethane, followed by chlorotriphenylsilane.

The products so obtained have a hybrid structure of tetraphenylsilane and the aromatic amine of carbazole and may be used as host material for dopants for organic light emitting diode (OLED). When the invented compound is used as host material for dopants of OLED, its glass transition temperature may be as high as 140° C. or above, its triplet-state excitation energy may be greater than 2.9 eV.

The present invention also discloses a new host material for dopants for OLEDS. The host material comprises a tetraphenylsilane-carbazole compound.

In addition, a new structure of light emit layer for OLED is also disclosed. The light emit layer comprises a host material comprising a tetraphenylsilane-carbazole compound and dopants dispersed in the host material.

These and other objectives and advantages of the present invention may be clearly understood from the detailed description by referring to the following drawings.

### BRIEF DESCRIPTION OF THE DRAWINGS

FIG. 1 shows glass transition temperature of the tetraphenylsilane-carbazole compound of this invention.

FIG. 2 illustrates chemical formulas of several examples of the tetraphenylsilane-carbazole compound of this invention.

FIG. 3 shows the triplet-state excitation energy of the tetraphenylsilane-carbazole compound of this invention in comparison with that of conventional mCP.

FIG. 4 illustrates structure of an OLED using the invented host material.

FIG. 5 shows current density, electroluminance, voltage, and external quantum efficiency of some embodiments of the present invention, when used as host material of OLED.

### DETAILED DESCRIPTION OF THE INVENTION

The present invention disclosed a new material to be used as host material for OLEDS. In the host material, suited dopants are dispersed. The host material comprises as major ingredient a tetraphenylsilane-carbazole compound having the general formula of:

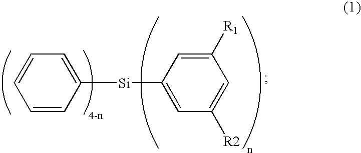

wherein R1 and R2 are H, halogen or carbazole having the formula of 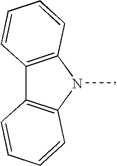
respectively, with at least one of R1 and R2 being carbazole; n=1, 2, 3 or 4; and wherein Si and N substituents are in meta positions on the benzene ring; or

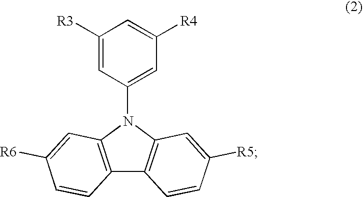

wherein R3, R4, R5 and R6 are H, halogen or tetraphenylsilane having the formula of 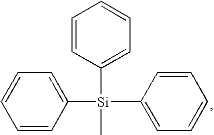
respectively, with at least one of R3, R4, R5 and R6 being tetraphenylsilane; and wherein Si and N substituents are in meta positions on the benzene ring.

The invented tetraphenylsilane-carbazole compounds may be prepared by mixing selected tetraphenylsilane with carbazole in the existence of additives and react under heated conditions, or by mixing selected carbazole with butyl metallic and reacting them under relatively lower temperature. In the first approach of the invented method, the tetraphenylsilane may have substituents in its benzene ring. The substituents may be one or more halogens. The reaction may be conducted under the presence of solvents, catalysts and additives. Suited solvents included: benzene, toluene, xylenes, durene, 1,4-dioxane, and dimethoxyethane (DME). Suited catalysts included: Pd(OAc)₂, Pd₂(dba)₃, (DPPE)PdCl₂, Pd(PPh₃)₄, and Pd(DPPF)Cl₂. Suited additives included: DPPF, DPPP, P(t-Bu)₃, BINAP, and P(o-tolyl)₃; Na(O-t-Bu), K(O-t-Bu), Cs₂CO₃, K₂CO₃, Na₂CO₃, K₃PO₄, and LiN(SiMe3)₂ for base additives. Other solvents, catalysts and/or additives may also be used in this reaction. The reaction temperature is preferably above 85° C., more preferably above 135° C. In the second approach of the invented method, the butyl metallic is preferably butyl alkali and more preferably butyllithium. The reaction temperature is preferably below 20° C., more preferably below 0° C.

The invented tetraphenylsilane-carbazole compounds may be used as major ingredient for host material for dopants of OLEDs. The host material may be prepared as a thin layer of 1˜100 nm, preferable 30 nm, or in a thin layer with any known art. Suited dopants may be dispersed into the host material using any applicable technology. The product so obtained may be used as efficient host for the phosphorescent light-emitters of OLEDS.

### EMBODIMENTS

In the followings, examples will be given to show approaches in the preparation of the invented tetraphenylsilane-carbazole compounds. It is noted that these examples are only preferred examples and are used to illustrate the invention. They shall not be used to limit the scope of this invention.

### Embodiment I

### Preparation of (3,3′,5,5′-Tetra(9H-carbazol-9-yl)tetraphenylsilane) (TPSCB3)

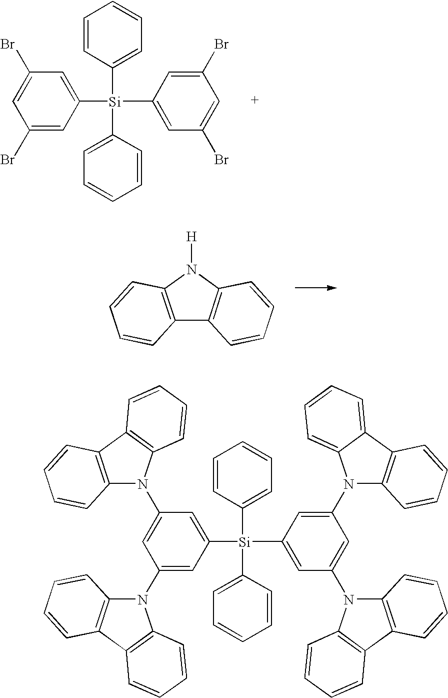

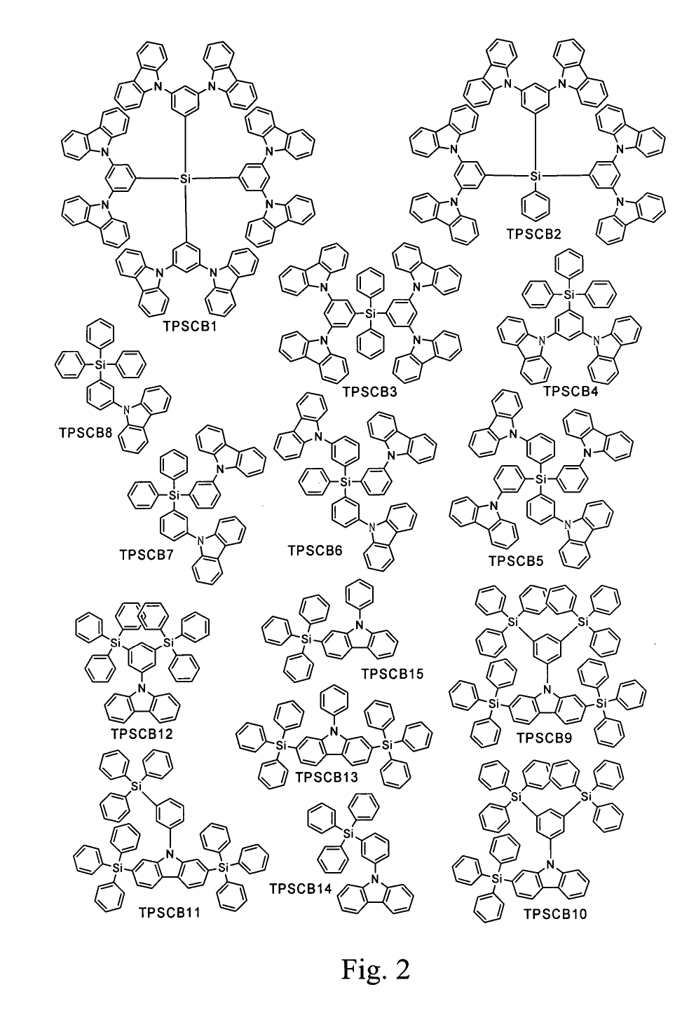

Under the protection of nitrogen atmosphere, 3,3′,5,5′-tetrabromo-tetraphenylsilane (4.17 g, 6.40 mmol), carbazole (5.34 g, 30.7 mmol), potassium carbonate (12.72 g, 92.0 mmol) and palladium acetate (0.057 g, 0.25 mmol) were mixed together in dry xylenes (38 mL). After the rapid addition of tri-t-butylphosphine (0.2 mL, 0.8 mmol), the mixture was heated to refluxing for 16 hours. After cooling to room temperature, the reaction solution was extracted by deionized water twice. The solution was dried by magnesium sulfate and evaporated till dryness under reduced pressure. The solid residue was purified by flash column chromatography (silica gel, dichloromethane/hexanes 2/8). Yield white solid 4.31 g (68%). ¹H NMR(CDCl₃, 400 MHz): 8.06-8.10 (m, 8H), 7.97-7.98 (d, 4H, J=2.0 Hz), 7.89-7.90 (t, 2H, J=2.0 Hz), 7.78-7.80 (m, 4H), 7.44-7.50(m, 6H), 7.37-7.42 (m,8H), 7.18-7.24(m,16H). ¹³C NMR(CDCl₃, 100 MHz): 140.4, 139.4, 138.2, 136.2, 132.8, 131.9, 130.7, 128.6, 126.3, 126.2, 123.7, 120.4, 109.5. FAB-MS: calcd MW, 996.36; m/e=997.1(M+H)⁺. Anal, Found (calc) for C₇₂H₄₈N₄Si, C: 86.73(86.71), H: 4.73(4.85), N: 5.43(5.62). T_{g}=141° C., T_{c}=not detected, Tₘ=not detected, T_{d}=440° C. The product is labeled as TPSCB3, as shown in FIG. 2.

### Embodiment II

### Preparation of 3,5-Di(9H-carbazol-9-yl)tetraphenylsilane (TPSCB4)

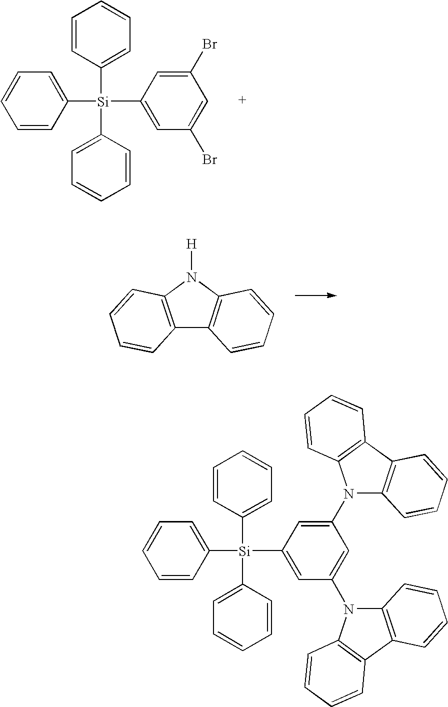

3,5-Dibromotetraphenylsilane (3.00 g, 6.10 mmol), carbazole (2.56 g, 14.6 mmol), potassium carbonate (6.04 g, 43.7 mmol) and palladium acetate (0.028 g, 0.12 mmol) were mixed together in dry xylenes (30 mL). The synthesis was performed in a similar fashion as that of Embodiment I. Flash column chromatography (silica gel, dichloromethane/hexanes 1/9) yielded white solid 2.18 g (54%). ¹H NMR(CDCl₃, 400 MHz): 8.08-8.10 (d, 4H, J=7.6 Hz), 7.86 (s, 3H), 7.66-7.68 (d, 6H, J=6.3 Hz), 7.34-7.46 (m, 17H), 7.25-7.27 (d, 4H, J=7.3 Hz). ¹³C NMR(CDCl₃, 100 MHz): 140.4, 138.9, 136.3, 133.0, 132.8, 130.1, 128.2, 126.1, 125.5, 123.6, 120.4, 120.3, 109.7. FAB-MS: calcd MW, 666.25; m/e=667.1(M+H)⁺. Anal, Found (calc) for C₄₈H₃₄N₂Si, C: 86.31(86.45), H: 5.15(5.14), N: 4.36(4.20). T_{g}=101° C., T_{c}=not detected, Tₘ=274, T_{d}=372° C. The product is labeled as TPSCB4 as shown in FIG. 2.

### Embodiment III

### Preparation of 3,3′,3″-Tri(9H-carbazol-9-yl)tetraphenylsilane (TPSCB6)

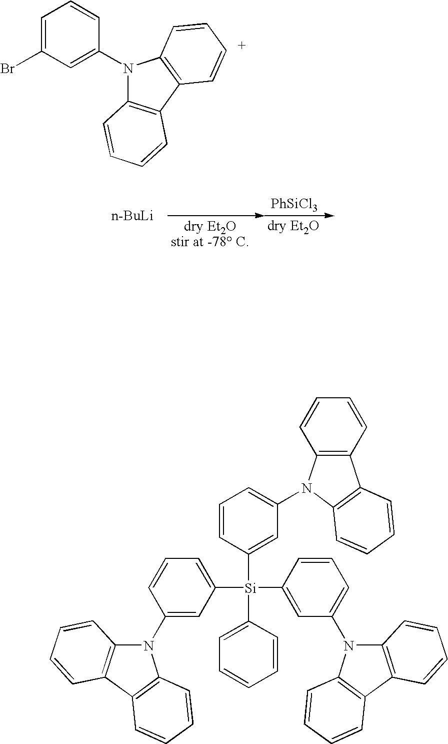

Under the protection of nitrogen atmosphere, N-(3-bromophenyl)carbazole (6.49 g, 20.1 mmol) was dissolved in dry diethyl ether (40 mL). At −78° C., 1,6 M of n-butyllithium hexane solution (19 mL, 30.4 mmol) was added to the ether reaction solution. The reaction solution was stirred and kept at low temperature for 2 hours. A dry diethyl ether solution (40 mL) of trichlorophenylsilane (2 mL, 9.5 mmol) was added to the reaction solution and stirred at −78° C. for another 2 hours. The reaction was worked up in a similar fashion as that of Embodiment I. Flash column chromatography (silica gel, dichloromethane/hexanes 2/8) yielded white solid 1.74 g (34%). ¹H NMR(CDCl₃, 400 MHz): 8.06-8.08 (d, 6H, J=7.0 Hz), 7.85 (s, 3H), 7.703-7.74 (m, 5H), 7.63 (m, 63H), 7.41-7.43 (m, 3H), 7.15-7.26 (m, 18H). ¹³C NMR(CDCl₃, 100 MHz): 140.6, 137.7, 136.2, 135.8, 135.0, 134.5, 132.4, 130.4, 129.8, 128.6, 128.4, 125.9, 123.4, 120.2, 120.0, 109.6. FAB-MS: calcd MW, 831.31; m/e=832.0(M+H)⁺. Anal, Found (calc) for C₆₀H₄₁N₃Si, C: 86.59(86.61), H: 4.95(4.97), N: 5.21(5.05). T_{g}=85° C., T_{c}=not detected, Tₘ=not detected, T_{d}=423° C. The product is labeled as TPSCB6 as shown in FIG. 2.

### Embodiment IV

### Preparation of 3,3′-Di(9H-carbazol-9-yl)tetraphenylsilane (PTSCB7)

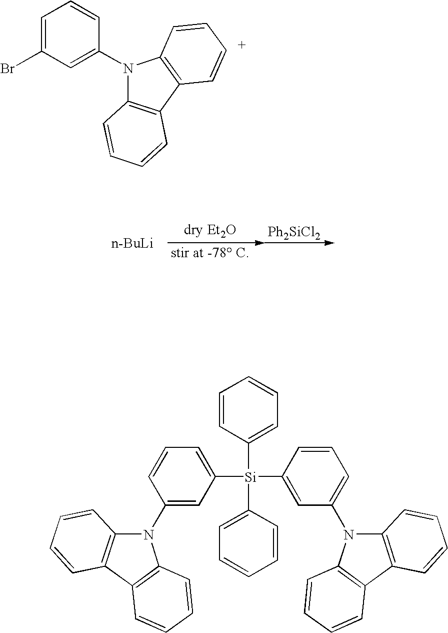

N-(3-bromophenyl)carbazole (6.31 g, 19.6 mmol) was dissolved in dry diethyl ether (40 mL). At −78° C., 1,6 M of n-butyllithium hexane solution (14.8 mL, 23.7 mmol) was added to the ether reaction solution. The synthesis was performed with dry diethyl ether solution (40 mL) of dichlorodiphenylsilane (2 mL, 9.5 mmol) in a similar fashion as that of Embodiment III, provided, however, that the product was precipitated out of the reaction solution and that the filtration isolated the product was washed with excess amount of hexanes. Yield white solid 3.04 g (48%). ¹H NMR(CDCl₃, 400 MHz): 8.14-8.16 (d, 4H, J=8.0 Hz), 7.88-7.89 (d, 2H, J=4.0 Hz), 7.68-7.78 (m, 10H), 7.45-7.50 (m, 6H), 7.26-7.39 (m, 12H). ¹³C NMR(CDCl₃, 100 MHz): 140.7, 137.6, 136.5, 136.3, 135.1, 134.5, 133.0, 130.1, 129.6, 128.3, 128.2, 125.9, 123.4, 120.2, 120.0, 109.7. FAB-MS: calcd MW, 666.25; m/e=666.1(M)⁺. Anal, Found (calc) for C₄₈H₃₄N₂Si, C: 86.65(86.45), H: 5.11(5.14), N: 4.58(4.20). T_{g}=84° C., T_{c}=not detected, Tₘ=185° C., T_{d}=377° C. The product is labeled as TPSCB7 as shown in FIG. 2.

### Embodiment V

### Preparation of 3-(9H-carbazol-9-yl)tetraphenylsilane (TPSCB8)

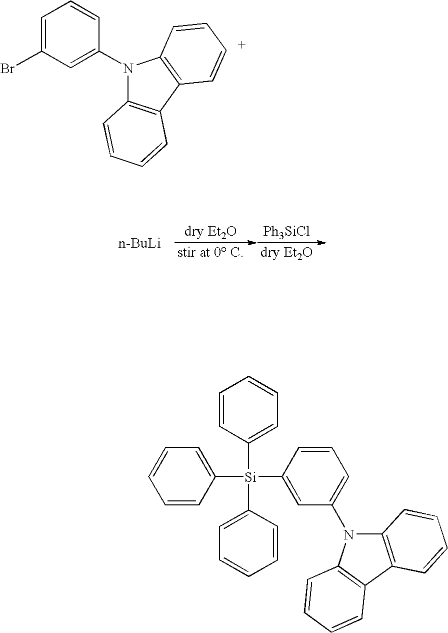

N-(3-bromophenyl)carbazole (6.31 g, 19.6 mrnmol) in dry diethyl ether (15 mL), 1.6 M of n-butyllithium hexane solution (7.2. mL, 11.5 mmol) and chlorotrphenylsilane (2.22 g, 7.5 mmol) in dry ether (15 mL) were mixed. The synthesis was performed in a similar fashion as that of Embodiment IV. Yield white solid 2.82 g (75%). ¹H NMR(CDCl₃, 400 MHz): 8.10-8.12 (d, 2H, J=7.7 Hz), 7.80 (s, 1H), 7.63-7.64 (m, 9H), 7.34-7.47 (m, 13H), 7.24-7.28 (m, 2H). ¹³C NMR (CDCl₃, 100 MHz): 140.7, 137.4, 137.1, 136.4, 135.1, 134.5, 133.6, 129.8, 129.4, 128.0, 127.9, 125.8, 123.4, 120.2, 119.9, 109.8. FAB-MS: calcd MW, 501.19; m/e=502.1 (M+H)⁺. Anal, Found (calc) for C₃₆H₂₇NSi, C: 86.19(86.19), H: 5.30(5.42), N: 2.61(2.79). T_{g}=54° C., T_{c}=not detected, Tₘ=168° C., T_{d}=314° C. The product is labeled as TPSCB8 as shown in FIG. 2.

These and other tetraphenylsilane-carbazole compounds prepared according to the invented method are listed in FIG. 2 for reference.

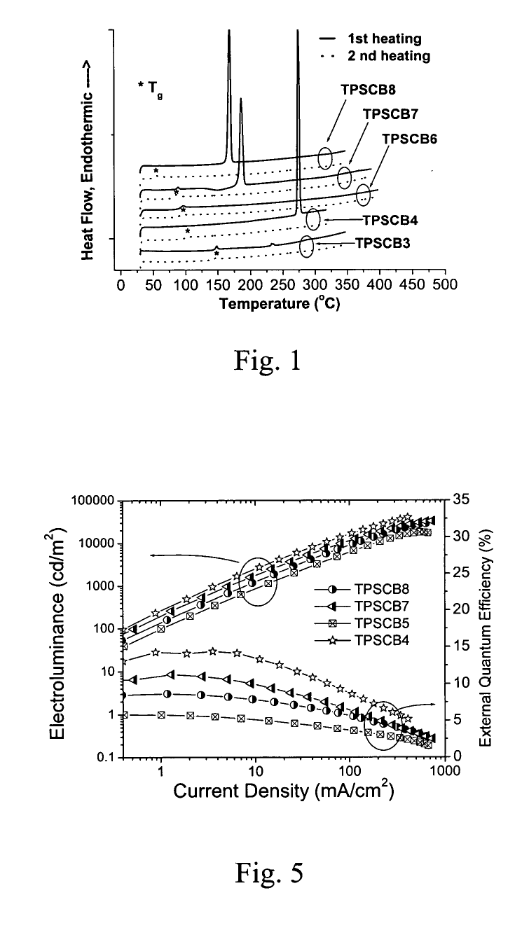

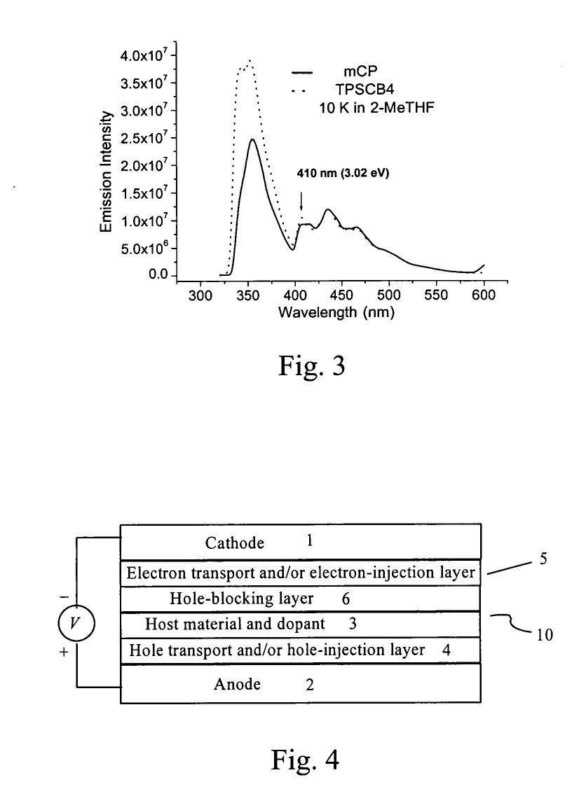

TPSCB3, TPSCB4, TPSCB6, TPSCB7 and TPSCB8 were subject to tests to obtain their glass transition temperatures Tgs. The results are shown in FIG. 1. The results revealed that for most embodiments their Tgs are over 80° C., while some of them were over 100° C. Experiments also showed that their triplet-state excitation energy is higher than 2.9 eV (or wavelength shorter than 430 nm). TPSCB4 was subjected to tests to obtain its triplet-state excitation energy and compare with that of mCP. The results are shown in FIG. 3.

The invented tetraphenylsilane-carbazole compound may be used as major ingredient for host material for dopants of OLEDs. The host material may be prepared as a substrate layer or in a substrate layer in the thickness of about 1˜100 nm, preferably 30 nm. The host material layer may be prepared separately or during the preparation of the OLED, as one of its layers. The host material may be prepared using any known art, including thermal vacuum deposition, spin-coating, dip-coating, and inject-printing. Dopants may be dispersed into the host material using any applicable technology. Suited dopants include: iridium, platinum, osmium, ruthenium, rhodium, or rhenium complexes with principle emission wavelength less than 550 nm, more preferable less than 500 nm. Any applicable method may be used in dispersing the dopants. Suited methods include: thermal vacuum deposition, spin-coating, dip-coating, and inject-printing. The dopants may be added during or after the preparation of the host material layer. The product so obtained may be used as the host material of light-emitting layer doped with above-mentioned metal complexes of OLEDs.

In application, the host material prepared according to the present invention may be used in an electronic device comprising at least one photoactive layer positioned between two electrical contact layers, wherein at least one layer of the device includes the tetraphenylsilane-carbazole hybrid compound of the invention. FIG. 4 shows the structure of an OLED adopting the invented host material. As shown in this figure, the OLED device 10 has a cathode 1, an anode 2 and a photoactive layer 3 which contains a host material and dopants. It may have additional layers such as hole transport layer (or electron injection layer) 4, electron transport layer (or hole injection layer) 5, and/or hole-blocking layer 6. In the example of FIG. 4, the hole transport layer 4 may be (N,N′-dinaphthalene-1-yl)-N,N′-diphenylbenzidine (NPB), while the electron transport layer 5 may be 2,2′,2″-(1,3,5-phenylene)tris(1-phenyl-1-H-benzimidazole) (TPBI). In this example the anode 2 may be indium tin oxide (ITO) and the cathode 1 may be LiF/Al. Also in this example the dopant metal complex may be iridium (iii) bis(4,6-difluorophenylpyridinato)picolate (FIrpic) with principle emission at 470 nm. TPSCB3, TPSCB4, TPSCB7, and TPSCB8 were prepared and applied to an LED with the structure as shown in FIG. 4, as its host material. The LED is subjected to tests to obtain the OLED performance (current density, electroluminance, voltage, and external quantum efficiency) of these materials. The results are shown in FIG. 5.

As the present invention has been shown and described with reference to preferred embodiments thereof, those skilled in the art will recognize that the above and other changes may be made therein without departing form the spirit and scope of the invention.

What is claimed is:

1. A tetraphenylsilane-carbazole compound having the general formula of: 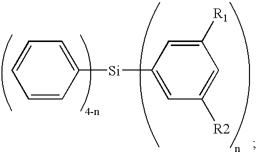
wherein R1 and R2 are respectively H, halogen or carbazole having the formula of 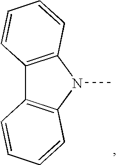
with at least one of R1 and R2 being carbazole; n=1, 2, 3 or 4; and wherein Si and N substituents are in meta positions on the benzene ring.

2. A tetraphenylsilane-carbazole compound having the general formula of: 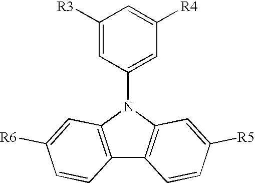
wherein R3, R4, R5 and R6 are H, halogen or tetraphenylsilane having the formula of 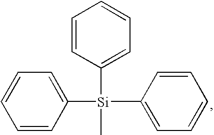
with at least one of R3, R4, R5 and R6 being tetraphenylsilane; and wherein Si and N substituents are in meta positions on the benzene ring.

3. Method for preparation of tetraphenylsilane-carbazole compound having the general formula of: 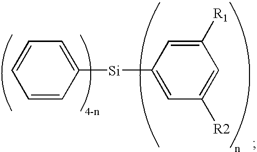
wherein R1 and R2 are respectively H, halogen or carbazole having the formula of 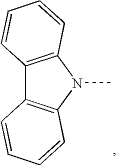
with at least one of R1 and R2 being carbazole; n=1, 2, 3 or 4; and wherein Si and N substituents are in meta positions on the benzene ring;
comprising the steps of mixing a tetraphenylsilane with a carbazole and reacting under heated conditions.

4. The method according to claim 3, wherein said tetraphenylsilane comprises one or more halogen substituents in its benzene ring.

5. The method according to claim 4, wherein said halogen substituents is chlorine, bromine, or iodine.

6. The method according to claim 3, wherein said reaction is conducted under the temperature of above 85° C.

7. The method according to claim 6, wherein said reaction is conducted under the temperature of above 135° C.

8. Method for preparation of tetraphenylsilane-carbazole compound having the general formula of: 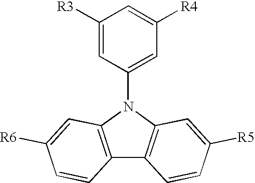
wherein R3, R4, R5 and R6 are H, halogen or tetraphenylsilane having the formula of 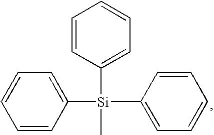
with at least one of R3, R4, R5 and R6 being tetraphenylsilane; and wherein Si and N substituents are in meta positions on the benzene ring;
comprising the steps of mixing a carbazole with a butyl metallic and reacting them under relatively lower temperature.

9. The method according to claim 8, wherein said butyl metallic is butyl alkali.

10. The method according to claim 4, wherein said butyl metallic is butyllithum.

11. The method according to claim 3, wherein said reaction is conducted under the temperature of below 20° C.

12. The method according to claim 6, wherein said reaction is conducted under the temperature of below 0° C.

13. Host material for dopants of organic light emitting diode, comprising a tetraphenylsilane-carbazole compound having the general formula of: 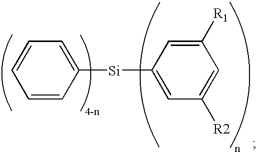
wherein R1 and R2 are respectively H, halogen or carbazole having the formula of 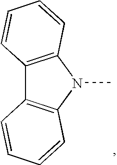
with at least one of R1 and R2 being carbazole; n=1, 2, 3 or 4; and wherein Si and N substituents are in meta positions on the benzene ring.

14. Host material for dopants of organic light emitting diode, comprising a tetraphenylsilane-carbazole compound having the general formula of: 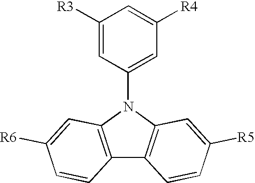
wherein R3, R4, R5 and R6 are H, halogen or tetraphenylsilane having the formula of 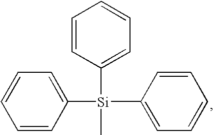
with at least one of R3, R4, R5 and R6 being tetraphenylsilane; and wherein Si and N substituents are in meta positions on the benzene ring.

15. An organic light emitting diode, comprising a photoactive layer comprising at least one dopant and a host material; wherein said host material comprises a tetraphenylsilane-carbazole compound having the general formula of: 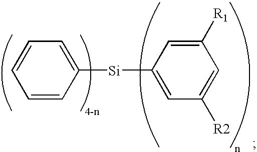
wherein R1 and R2 are respectively H, halogen or carbazole having the formula of 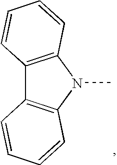
with at least one of R1 and R2 being carbazole; n=1, 2, 3 or 4; and wherein Si and N substituents are in meta positions on the benzene ring.

16. An organic light emitting diode, comprising a photoactive layer comprising at least one dopant and a host material; wherein said host material comprises a tetraphenylsilane-carbazole compound having the general formula of: 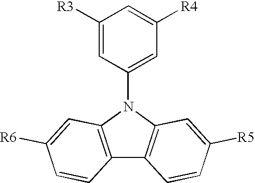
wherein R3, R4, R5 and R6 are H, halogen or tetraphenylsilane having the formula of 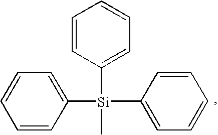
with at least one of R3, R4, R5 and R6 being tetraphenylsilane; and wherein Si and N substituents are in meta positions on the benzene ring.

17. Method for preparation of host material for dopants of host material of organic light emitting diodes, comprising the steps of:
preparing an amount of tetraphenylsilane-carbazole compound having the general formula of: 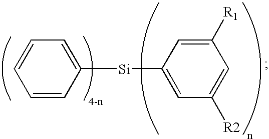
wherein R1 and R2 are respectively H, halogen or carbazole having the formula of 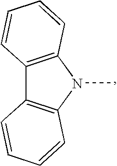
with at least one of R1 and R2 being carbazole; n=1, 2, 3 or 4; and wherein Si and N substituents are in meta positions on the benzene ring; and forming said amount of tetraphenylsilane-carbazole compound into a layer.

18. Method for preparation of host material for dopants of host material of organic light emitting diodes, comprising the steps of:
preparing an amount of tetraphenylsilane-carbazole compound having the general formula of: 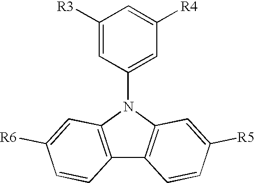
wherein R3, R4, R5 and R6 are H, halogen or tetraphenylsilane having the formula of 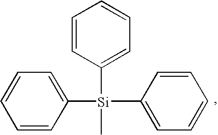
with at least one of R3, R4, R5 and R6 being tetraphenylsilane; and wherein Si and N substituents are in meta positions on the benzene ring; and
forming said amount of tetraphenylsilane-carbazole compound into a layer.

19. Method for preparation of photoactive layer for organic light emitting diodes, comprising the steps of:
preparing an amount of tetraphenylsilane-carbazole compound having the general formula of: 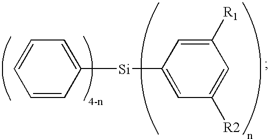
wherein R1 and R2 are respectively H, halogen or carbazole having the formula of 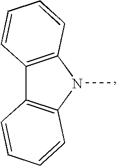
with at least one of R1 and R2 being carbazole; n=1, 2, 3 or 4; and wherein Si and N substituents are in meta positions on the benzene ring; doping an amount of dopant in said amount of tetraphenylsilane-carbazole compound; and
forming said doped composition into a layer.

20. Method for preparation of photoactive layer for organic light emitting diodes, comprising the steps of:
preparing an amount of tetraphenylsilane-carbazole compound having the general formula of: 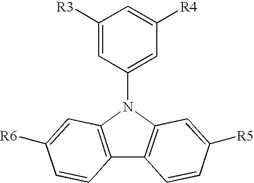
wherein R3, R4, R5 and R6 are H, halogen or tetraphenylsilane having the formula of 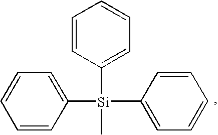
with at least one of R3, R4, R5 and R6 being tetraphenylsilane; and wherein Si and N substituents are in meta positions on the benzene ring;
doping an amount of dopant in said amount of tetraphenylsilane-carbazole compound; and
forming said doped composition into a layer.

21. Method for preparation of photoactive layer for organic light emitting diodes, comprising the steps of:
preparing an amount of tetraphenylsilane-carbazole compound having the general formula of: 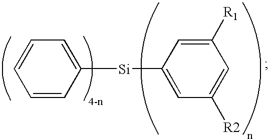
wherein R1 and R2 are respectively H, halogen or carbazole having the formula of 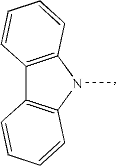
with at least one of R1 and R2 being carbazole; n=1, 2, 3 or 4; and wherein Si and N substituents are in meta positions on the benzene ring;
forming said amount of tetraphenylsilane-carbazole compound into a layer; and doping an amount of dopant in said tetraphenylsilane-carbazole compound layer.

22. Method for preparation of photoactive layer for organic light emitting diodes, comprising the steps of:
preparing an amount of tetraphenylsilane-carbazole compound having the general formula of: 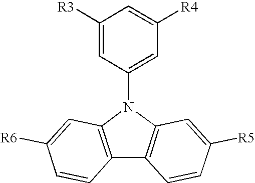
wherein R3, R4, R5 and R6 are H, halogen or tetraphenylsilane having the formula of 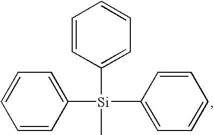
with at least one of R3, R4, R5 and R6 being tetraphenylsilane; and wherein Si and N substituents are in meta positions on the benzene ring;
forming said amount of tetraphenylsilane-carbazole compound into a layer; and doping an amount of dopant in said tetraphenylsilane-carbazole compound layer.

23. An organic light emitting diode, comprising at least one cathode, at least one anode and at least one photoactive layer; wherein said photoactive layer comprises at least one dopant and a host material comprising a tetraphenylsilane-carbazole compound having the general formula of: 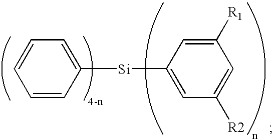
wherein R1 and R2 are respectively H, halogen or carbazole having the formula of 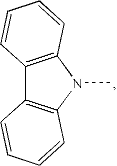
with at least one of R1 and R2 being carbazole; n=1, 2, 3 or 4; and wherein Si and N substituents are in meta positions on the benzene ring.

24. An organic light emitting diode, comprising at least one cathode, at least one anode and at least one photoactive layer; wherein said photoactive layer comprises at least one dopant and a host material comprising a tetraphenylsilane-carbazole compound having the general formula of: 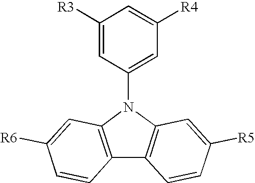
wherein R3, R4, R5 and R6 are H, halogen or tetraphenylsilane having the formula of 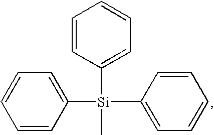
with at least one of R3, R4, R5 and R6 being tetraphenylsilane; and wherein Si and N substituents are in meta positions on the benzene ring.

25. The organic light emitting diode according to claim 23, further comprising a hole transport layer and an electron transport layer.

26. The organic light emitting diode according to claim 24, further comprising a hole transport layer and an electron transport layer.

27. The organic light emitting diode according to claim 25, further comprising a hole blocking layer.

28. The organic light emitting diode according to claim 26, further comprising a hole blocking layer.
